(19) United States
(12) Patent Application Publication
(10) Pub. No.: US 2017/0081177 A1
(43) Pub. Date: Mar. 23, 2017

(54) INTERPOSER FOR MOUNTING A VERTICALLY INTEGRATED HYBRID COMPONENT ON A COMPONENT CARRIER

(71) Applicant: Robert Bosch GmbH, Stuttgart (DE)

(72) Inventors: Reinhard Neul, Stuttgart (DE); Johannes Classen, Reutlingen (DE); Torsten Kramer, Wannweil (DE); Jochen Reinmuth, Reutlingen (DE); Mirko Hattass, Stuttgart (DE); Lars Tebje, Reutlingen (DE); Daniel Christoph Meisel, Pittsburgh, PA (US); Ralf Reichenbach, Esslingen (DE); Friedjof Heuck, Stuttgart (DE); Antoine Puygranier, Stuttgart (DE)

(73) Assignee: Robert Bosch GmbH, Stuttgart (DE)

(21) Appl. No.: 15/311,253

(22) PCT Filed: May 29, 2015
(86) PCT No.: PCT/EP2015/061946

§ 371 Date: Nov. 15, 2016

(30) Foreign Application Priority Data
Jun. 6, 2014 (DE) 102014210912.4

(51) Int. Cl. B81B 7/00

(52) U.S. Cl. CPC B81B 7/0048; B81B 2207/07; B81B 2207/096; B81B 2207/012

(57) ABSTRACT

An interposer is provided which is made up of a flat carrier substrate including at least one front wiring plane, in which front terminal pads are formed for mounting a component on the interposer, including at least one rear wiring plane, in which rear terminal pads are formed for mounting on a component carrier, the front terminal pads and the rear terminal pads being arranged offset from each other; and including vias for electrical connection of the at least one front wiring plane and the at least one rear wiring plane. The carrier substrate includes at least one edge section and at least one center section, which are at least largely mechanically decoupled via a stress-decoupling structure. The front terminal pads are arranged exclusively on the center section for mounting the component, while the rear terminal pads are arranged exclusively on the edge section for mounting on a component carrier.

### BACKGROUND INFORMATION

The present invention relates to an interposer which is suitable in particular for mounting a vertically integrated hybrid component on a component carrier. The interposer is made up of a flat carrier substrate including at least one front wiring plane and at least one rear wiring plane. Terminal pads are formed in the front wiring plane for mounting the component on the interposer, and rear terminal pads are formed in the rear wiring plane for mounting on a component carrier. The front terminal pads and the rear terminal pads are arranged offset from each other. Vias are formed in the carrier substrate, with the aid of which the front and the rear wiring planes are electrically connected. In addition, a stress decoupling structure is formed in the carrier substrate.

Vertically integrated hybrid components generally include at least one MEMS element with a micromechanical sensor function or actuator function, and at least one ASIC element with circuit functions for the signal processing for the MEMS functionality. The elements of a vertically integrated hybrid component are arranged in a chip stack, which may be mounted as a chip-scale package on a component carrier without additional outer packaging. In this case, flip-chip techniques are typically used.

Important applications for vertically integrated hybrid components in the automobile and consumer electronics sectors include the detection of accelerations, rotation rates, magnetic fields, or pressures. Here, the respective measured variable is detected and converted into electrical signals with the aid of the MEMS element. These signals are then processed and evaluated with the aid of the ASIC circuit functions.

The component design of vertically integrated hybrid components makes a high level of miniaturization possible with a high level of functional integration, since the individual element components are stacked, so that an outer packaging of the individual chips and the component may be dispensed with altogether.

However, the direct mounting of such chip-scale packages results in deformations of the component carrier being very directly coupled into the MEMS element and the MEMS structure. Deformations of the application circuit board may occur during the course of the aging of the device, but may also be attributed to temperature and/or pressure fluctuations, caused by moisture, or be mounting-related; in any case, they generally result in mechanical stresses in the component structure, which may greatly impair the MEMS function. In the case of sensor components, this may result in an undesirable and undefined sensor behavior. Thus, for example, the sensitivity may change, or a drift in the sensor signal may also occur.

U.S. Pat. No. 6,050,832 describes dealing with problems which occur in flip-chip mounting of comparatively large chips. In this case, the chips are mounted on a carrier with the active front side via so-called “ball grid arrays,” i.e., a plurality of solder balls arranged in a grid, the solder balls being used simultaneously for the mechanical fixing and the electrical contacting of the chip. The solder ball grid generally extends over the entire chip surface, in order to fix the chip preferably across the entire surface on the one hand, and to implement a preferably large number of electrical chip terminals on the other hand. These solder connections are subject to high mechanical stresses. Among other things, this may be attributed to different thermal coefficients of expansion of the carrier material, the chip material, and the solder material.

U.S. Pat. No. 6,050,832 A describes improving the reliability and service life of the solder joints of such a ball grid array with the aid of an interposer of the type specified at the outset, the design of a connection grid over the entire surface, however, being maintained. According to U.S. Pat. No. 6,050,832 A, each individual connection point of such a grid is stress-decoupled. For this purpose, in the interposer, an elastic tongue is formed for each individual connection point, acting as a stress decoupling structure. On each tongue structure, a front terminal pad is arranged for the chip, and a rear terminal pad is arranged for mounting, namely, offset from each other, so that the elastic tongue structure is able to absorb mechanical stresses in the connecting area.

### SUMMARY

The present invention provides an interposer design for reducing mounting-related mechanical stresses in the structure of a vertically integrated hybrid component, which enables a reliable mechanical fixing of the component to a component carrier and a space-saving electrical contacting of the component.

In accordance with the present invention, this may be achieved in that the carrier substrate of the interposer includes at least one edge section and at least one center section, which are at least largely mechanically decoupled by the stress-decoupling structure, and in that the front terminal pads are arranged exclusively on the center section for mounting the component, while the rear terminal pads are arranged exclusively on the edge section for mounting on a component carrier.

Accordingly, the center section of the interposer according to the present invention is provided exclusively for a central mechanical fixing and electrical contacting of the component. Thus, here, the component is not connected to the interposer over the entire surface, but rather only in a surface area which is significantly smaller than the footprint of the component. Mounting on the component carrier takes place exclusively via the edge section of the interposer. Although mechanical stresses in the component carrier are transmitted to this edge section, they are not introduced into the center section of the interposer, since the flexible stress-decoupling structure absorbs these stresses. The stress-decoupling structure establishes a spatial separation and a mechanical decoupling between the center section and the edge section of the interposer. Unlike the related art, here, the component-interposer and interposer-component carrier connections are thus not punctiformly mechanically decoupled, but rather according to chip areas. According to the present invention, the transmission of mechanical stresses in the component carrier to the component is thus prevented or at least impeded by two interacting actions, i.e., on the one hand by the centralized, comparatively small connecting surface between the component and the interposer, and on the other hand, by the flexible stress-decoupling structure of the interposer, which decouples the connecting area between the component and the interposer from the connecting area between the interposer and the component carrier.

There are various options for implementing an interposer according to the present invention, for example, which relate to the layout of the front and rear wiring planes with the terminal pads for the component and mounting on the component carrier. Finally, the function and the footprint of the component or components for which the interposer is intended are always to be taken into account. The connecting techniques which are to be used for mounting the component on the interposer on the one hand, and for mounting the interposer on the component carrier on the other hand, also affect the implementation of the interposer according to the present invention. In addition, it is meaningful to take into account the type of component carrier when selecting the material for the carrier substrate of the interposer, for example, with respect to similar thermal coefficients of expansion. There are also various options for forming the stress-decoupling structure in the carrier substrate of the interposer.

In one advantageous specific embodiment of the present invention, the stress-decoupling structure of the interposer is implemented in the form of a trench structure. Since the carrier substrate of the interposer is thinned in the trench area, deformations preferably occur in this area. Mechanical stresses in the component carrier may thus be selectively introduced into the interposer and kept away from the connecting area of the component. The stress absorption is largely a function of the geometry of the trench structure. Trench structures which include multiple trenches running essentially in parallel, rather than just one trench, are particularly advantageous. These may be formed in the front side and/or in the rear side of the carrier substrate. A further advantage of trench structures for stress decoupling is that the center area of the interposer may be decoupled from the edge area equally on all sides, since trench structures may be formed circumferentially closed around the center area.

In an additional advantageous specific embodiment of the present invention, the stress-decoupling structure of the interposer includes a slot structure having one or multiple individual slots which extend over the entire thickness of the carrier substrate from its front side to its rear side. Here, the slots are concatenated circumferentially around the center area, in order to decouple this area mechanically from the edge area.

Here as well, the stress-decoupling structure may include multiple concatenations of slots running essentially in parallel, which are advantageously arranged offset from each other.

In addition to a slot structure, the stress-decoupling structure of the interposer according to the present invention may, for example, also include spring elements which are formed in the carrier substrate between the at least one edge section and the at least one center section, in order to absorb the mechanical stresses of the component carrier.

The interposer design according to the present invention may also be extended to additional mounting or component variants. Thus, in one refinement of the present invention, at least one recess for an element is formed in the carrier substrate of the interposer, which is mounted on the bottom side of a vertically integrated hybrid component. In this case, front terminal pads are formed exclusively on at least one frame section of the recess for mounting this component, while rear terminal pads are formed exclusively on at least one other frame section of the recess for mounting on the component carrier. Here as well, the component-interposer and interposer-component carrier connections are separated according to chip areas, i.e., according to frame sections. Depending on the frame geometry, the individual frame sections are also more or less mechanically decoupled. In any case, this interposer variant helps to increase the functional density on the component carrier, since the chip surface of the component is used not only for the component functions, but also for the function of the additional element on the bottom side of the component.

As already mentioned, various materials are possible as a carrier substrate for the interposer according to the present invention. In addition to the material properties, which should be matched to the properties of the component carrier, the material selection should also take into account the complexity of production. From this point of view, silicon substrates and carriers made of a dielectric material are particularly suitable. It is simple to structure silicon carriers using standard methods of semiconductor technology and to provide them with vias, wiring planes, conductors, and terminal pads. It is also simple to structure dielectric carrier substrates using standard methods. In addition to the material, the implementation of vias and wiring planes is comparatively economical here.

### BRIEF DESCRIPTION OF THE DRAWINGS

As discussed above, there are various options for designing and refining the present invention in an advantageous manner. For this purpose, reference is made to the description herein of multiple exemplary embodiments of the present invention based on the figures.

FIGS. 1a and 1b each show a schematic sectional view of a vertically integrated hybrid component 100, which is mounted above an interposer 301 and 302 according to the present invention on a component carrier 110.

FIG. 2a shows a schematic sectional view of a vertically integrated hybrid component 100, which is mounted above a third interposer 303 according to the present invention on a component carrier 110.

FIG. 2b shows a top view onto this interposer 303.

FIG. 3a shows a schematic sectional view of a vertically integrated hybrid component 100 including an additional element 30 mounted on the rear side, which is arranged in a recess of an interposer 304 according to the present invention.

FIG. 3b shows a section through this structure in the area of the interposer surface.

### DETAILED DESCRIPTION OF EXAMPLE EMBODIMENTS

In all exemplary embodiments depicted herein, the vertically integrated hybrid component 100 is made up of a MEMS element 10 and an ASIC element 20. The two element components 10 and 20 are only schematically depicted here. MEMS element 10 may, for example, be an inertial sensor element including a deflectable sensor structure for detecting accelerations. The circuit functions of ASIC element 20 are advantageously used for processing and evaluating the sensor signals of MEMS element 10. MEMS element 10 and ASIC element 20 are interconnected both mechanically and electrically via a structured connecting layer 21 and form a chip stack or a chip-scale package. The external electrical contacting of the two elements 10 and 20 takes place with the aid of vias 22 in ASIC element 20, which are connected to a wiring plane 23 on the rear side of ASIC element 20. Terminal pads 24 for solder balls 25 are formed in this wiring plane 23, via which component 100 is connected both mechanically and electrically to an interposer according to the present invention for mounting on a component carrier 110. Component carrier 110 may, for example, be an application circuit board.

All interposers 301 through 304 depicted in the figures are made up of a flat carrier substrate 310. In this case, it may, for example, be a silicon substrate or a carrier made of a dielectric material. Carrier substrate 310 is equipped with a front wiring plane 320, in which front terminal pads 321 are formed for mounting component 100 on the respective interposer. A wiring plane 330 including rear terminal pads 331 for mounting on a component carrier 110 is also present on the rear side of the interposer. Wiring planes 320 and 330 are electrically insulated from carrier substrate 310 via insulation layers 311. Front terminal pads 321 are significantly smaller than rear terminal pads 331, since significantly smaller solder balls 25 or CU pillars may also be used for mounting component 100 on interposer 301, 302 and 303 than for external mounting on component carrier 110. In fact, for the internal contacting, other layout rules are used than for the external contacting on an application circuit board, for which solder balls 26 are used. In addition, front terminal pads 321 and rear terminal pads 331 are arranged offset from each other. The electrical connection between front wiring plane 320 and rear wiring plane 330 is established with the aid of vias 340 in carrier substrate 310. In this case, they may, for example, be copper TSVs which are insulated from carrier substrate 310.

In the carrier substrate of interposer 301 through 303, a stress-decoupling structure is formed in each case, which, according to the present invention, effectuates a mechanical decoupling of a center section 350 of carrier substrate 310 from an edge section 360 of carrier substrate 310. In addition, according to the present invention, front terminal pads 321 for mounting component 100 are arranged exclusively on center section 350, while rear terminal pads 331 for mounting on a component carrier 110 are arranged exclusively on edge section 360.

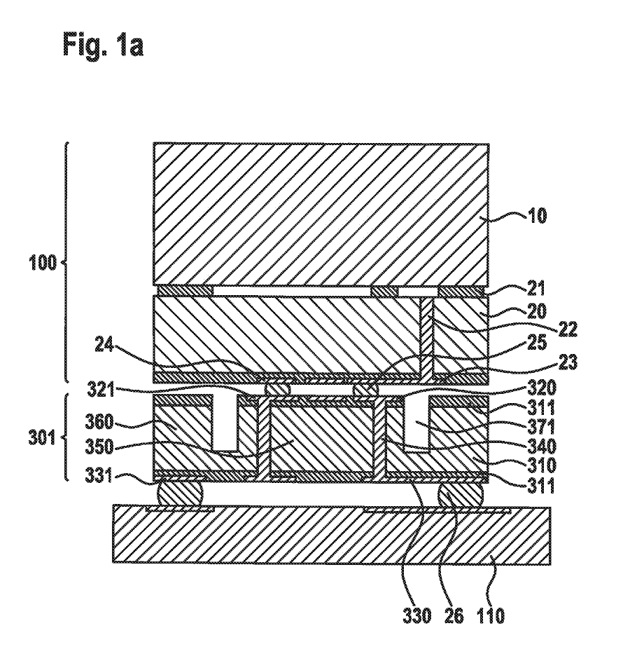

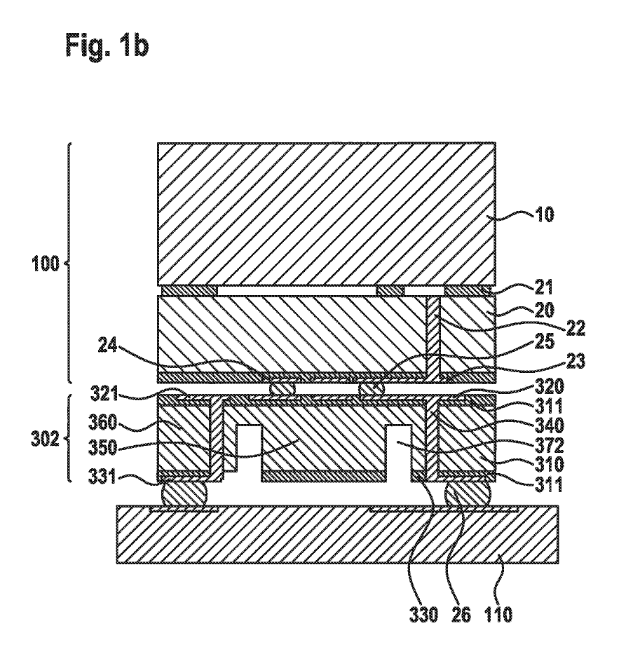

In the case of interposer 301 depicted in FIG. 1a, the stress-decoupling structure is implemented in the form of a trench 371 in the front side of carrier substrate 310, which defines center section 350 and separates it from frame-like edge section 360. This trench structure 371 is advantageously circumferentially closed, in the form of a rectangle, a circular ring, or an oval. In the case of a silicon substrate, it may, for example, be generated via trench etching in the carrier surface. In the case of other carrier materials, laser structuring is also possible for this. According to the present invention, front terminal pads 321 are arranged exclusively on center section 350. Since trench 371 is circumferentially closed, vias 340 are also formed in the center section of carrier substrate 310 and are connected via conductor sections in rear wiring plane 330 to rear terminal pads 331, which, according to the present invention, are arranged exclusively on edge section 360 of carrier substrate 310.

Likewise, in the case of interposer 302 depicted in FIG. 1b, the stress-decoupling structure is implemented in the form of a trench 372 which defines center section 350 and separates it from edge section 360. However, this trench structure 372 is formed in the rear side of carrier substrate 310. Again, front terminal pads 321 are arranged exclusively on center section 350, while rear terminal pads 331 are present exclusively on edge section 360. The electrical connection between front terminal pads 321 and rear terminal pads 331 is established here via conductor sections in front wiring plane 320 and vias 340, which are formed in the edge section of carrier substrate 310.

In the case of FIG. 1a as well as in the case of FIG. 1b, deformations of component carrier 110 are initially transmitted to edge sections 360 of interposer 301 and 302 via solder balls 26 and cause there a deformation of flexible stress-decoupling structure 371 and 372, i.e., in the trench area. Due to the mechanical decoupling of center section 350 and edge section 360, mechanical stresses in component carrier 110 are thus only partially transmitted into center section 350 of interposer 301 and 302. In addition, the central mounting of component 100 on center section 350 reduces the introduction of stress into component 100, since, the smaller the connecting surface is, i.e., the grid surface of solder balls 25, the less deformation energy is transmitted.

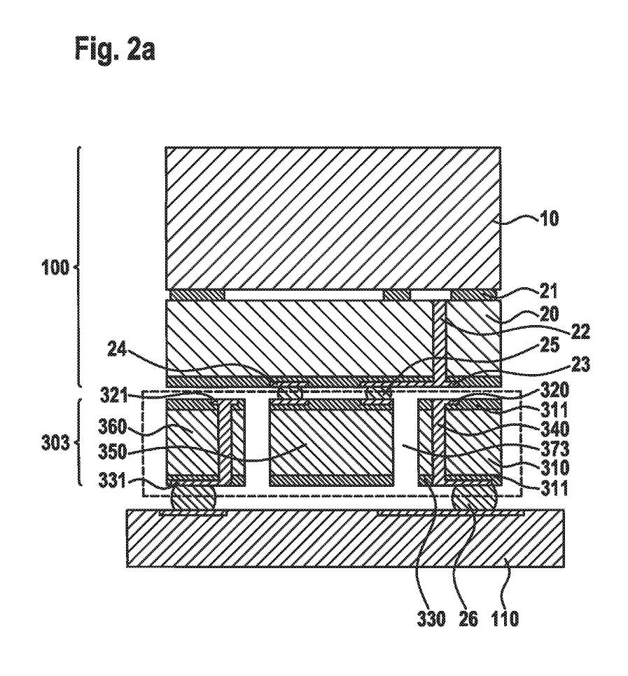

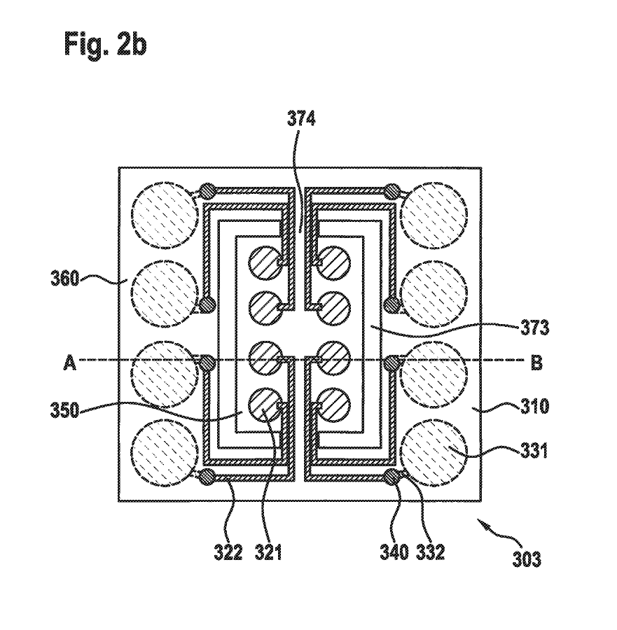

The structure depicted in FIG. 2a includes an interposer 303 whose stress-decoupling structure is implemented in the form of slots 373 and diaphragm-like spring elements 374. Slots 373 extend over the entire thickness of carrier substrate 310 and enclose center section 350 of carrier substrate 310 in a clamp-like manner, which is illustrated by the top view of FIG. 2b. Center section 350 is attached to edge section 360 only via the two spring elements 374 which are opposite each other. With the aid of this stress-decoupling structure, a particularly extensive mechanical decoupling between center section 350 and edge section 360 of carrier substrate 310 may be achieved.

In the exemplary embodiment depicted here, in addition to front terminal pads 321 being formed in front wiring plane 320, conductors 322 are formed which connect these terminal pads 321 to vias 340 arranged in edge section 360 in carrier substrate 310. These conductors 322 are routed via spring elements 374 from center section 350 into edge section 360. Here, the layout of rear conductors 332 and terminal pads 331 is depicted by dashed lines.

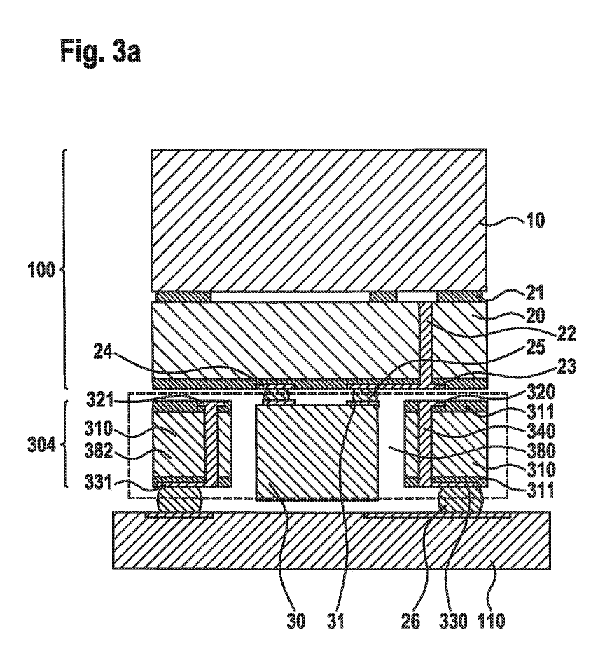

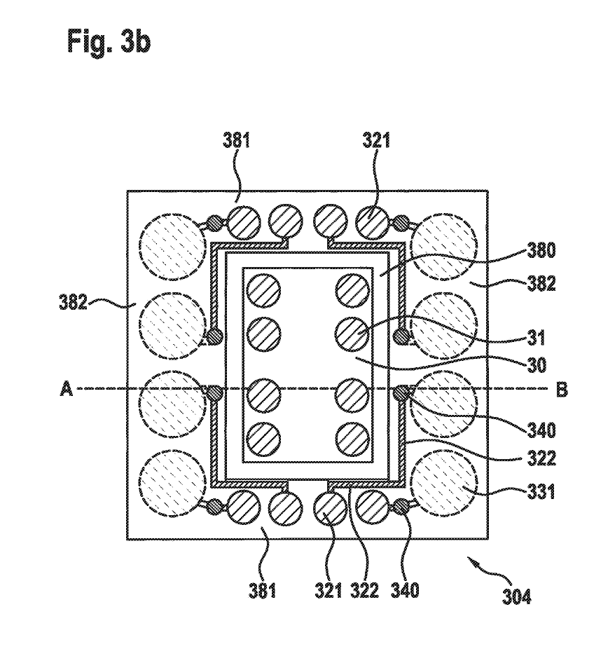

In interposer 304 depicted in FIGS. 3a, 3b, a recess 380 is formed in carrier substrate 310, which extends over the entire thickness of carrier substrate 310. This recess 380 is used as a receptacle for an additional element 30, which is mounted in flip-chip technology via terminal pads 31 and solder balls on the bottom side of component 100. In this case, for example, it may be an additional MEMS element, an additional ASIC element, or even an additional integrated sensor or actuator. The thickness of this element 30 may be scaled over a relatively large area and is even thicker here than carrier substrate 310 of interposer 304, which is balanced by solder balls 26. FIG. 3b illustrates that front terminal pads 321 are formed here exclusively on two opposite frame sections 381 of recess 380 for mounting component 100, while rear terminal pads 331 are formed exclusively on the other two opposite frame sections 382 of recess 380 for mounting on component carrier 110.

The exemplary embodiments described above demonstrate that the interposer design according to the present invention is extremely flexible and expandable. The layout may be adapted with comparatively little development complexity to various chip surfaces and balling variants, in order to satisfy specific requirements or footprints and/or pin arrangements.

1-8. (canceled)

9. An interposer for mounting a vertically integrated hybrid component on a component carrier, the interposer comprising:
a flat carrier substrate;
at least one front wiring plane, in which front terminal pads are formed for mounting the component on the interposer;
at least one rear wiring plane, in which rear terminal pads are formed for mounting on a component carrier, the front terminal pads and the rear terminal pads being arranged offset from each other;
vias for an electrical connection of the at least one front wiring plane and the at least one rear wiring plane; and
a stress-decoupling structure which is formed in the carrier substrate;
wherein the carrier substrate includes at least one edge section and at least one center section, which are at least largely mechanically decoupled by the stress-decoupling structure, and the front terminal pads are arranged exclusively on the center section for mounting the component, and the rear terminal pads are arranged exclusively on the edge section for mounting on the component carrier.

10. The interposer as recited in claim 9, wherein the stress-decoupling structure includes a trench structure which is made up of a trench or multiple trenches running in parallel in the front side and/or in the rear side of the carrier substrate.

11. The interposer as recited in claim 9, wherein the stress-decoupling structure includes a slot structure including one or multiple slots which extend over the entire thickness of the carrier substrate from its front side to its rear side.

12. The interposer as recited in claim 11, wherein the slot structure is made up of one or multiple concatenations of slots running in parallel, the slots of concatenations running in parallel being arranged offset from each other.

13. The interposer as recited in claim 9, wherein the stress-decoupling structure includes at least one spring element, which is formed in the carrier substrate between the at least one edge section and the at least one center section.

14. The interposer as recited in claim 9, wherein the carrier substrate includes at least one recess for an element which is mounted on the bottom side of the component, and front terminal pads are formed exclusively on at least one frame section of the recess for mounting the component, while rear terminal pads are formed exclusively on at least one other frame section of the recess for mounting on a component carrier.

15. The interposer as recited in claim 9, wherein the carrier substrate is a silicon substrate or a carrier made of a dielectric material.

16. A device, comprising:
an interposer for mounting a vertically integrated hybrid component on a component carrier, the interpose including a flat carrier substrate, at least one front wiring plane, in which front terminal pads are formed for mounting the component on the interposer, at least one rear wiring plane, in which rear terminal pads are formed for mounting on a component carrier, the front terminal pads and the rear terminal pads being arranged offset from each other, vias for an electrical connection of the at least one front wiring plane and the at least one rear wiring plane, and a stress-decoupling structure which is formed in the carrier substrate, wherein the carrier substrate includes at least one edge section and at least one center section, which are at least largely mechanically decoupled by the stress-decoupling structure, and the front terminal pads are arranged exclusively on the center section for mounting the component, and the rear terminal pads are arranged exclusively on the edge section for mounting on the component carrier;
the component including at least one MEMS element with at least one deflectable structural component, and one ASIC element with circuit functions for the MEMS function, the MEMS element and the ASIC element being interconnected via at least one connecting layer and forming a chip stack.
